(19) United States
(12) Patent Application Publication
(10) Pub. No.: US 2003/0232507 A1
(43) Pub. Date: Dec. 18, 2003

(54) Method for fabricating a semiconductor device having an ONO film

(75) Inventor: Cheng Shun Chen, Hsin-Chu (TW)

Correspondence Address: HAYNES BEFFEL & WOLFELD LLP, P O BOX 366, HALF MOON BAY, CA, 94019, US

(73) Assignee: Macronix International Co., Ltd., Hsinchu (TW)

(21) Appl. No.: 10/167,821

(22) Filed: Jun. 12, 2002

(51) Int. Cl. H01L 21/336; H01L 21/31; H01L 21/469

(52) U.S. Cl. 438/763; 438/954; 438/287

(57) ABSTRACT

A method for manufacturing an integrated circuit device includes forming a multi-layer film, such as an ONO film, on a surface of the substrate, the multi-layer film including the first layer of silicon oxide, a middle layer of silicon nitride, and a top layer of silicon oxide. The top layer of silicon oxide has an exposed surface. Next, the process involves exposing the exposed surface of the top layer of the multi-layer film to a plasma containing nitrogen radicals, to form a nitrided layer of oxide on the exposed surface. The nitrided layer of oxide on the top layer of silicon oxide in the multi-layer film has a thickness sufficient to protect the multi-layer film from damage during subsequent cleaning steps, used for example to prepare the substrate for formation of gate oxides in regions remote from the multi-layer film.

### BACKGROUND OF THE INVENTION

1. Field of the Invention

The present invention relates to integrated circuit manufacturing, including manufacturing of non-volatile memory devices, and more particularly to manufacturing of devices including oxide-nitride-oxide ONO films.

2. Description of Related Art

Oxide-nitride-oxide ONO films are used in manufacturing integrated circuit memory devices in a number of settings, usually as dielectric layers with high integrity. For example, floating gate memory devices typically comprise a source and drain in a substrate, a gate oxide over the substrate, floating gate polysilicon over the gate oxide, an ONO film over the floating gate, and a control gate polysilicon layer over the ONO film. Also, ONO films are used in so-called SONOS memory devices such as described in U.S. Pat. No. 6,011,725, in which the ONO film is used as a charge storage structure.

Typically, the structure of the memory cells in integrated circuit memory devices, including memory cells that include ONO films, requires a different sequence of manufacturing steps than does the structure of the logic devices used in peripheral circuitry on the integrated circuit. In the manufacturing of integrated circuits, the ONO film is usually formed on the substrate in the region of the integrated circuit in which the memory cells are formed. Then, regions on the integrated circuit in which peripheral devices are formed are prepared for formation of a gate oxide. The steps involved in preparing the substrate for formation of a gate oxide typically include cleaning steps prior to gate oxide formation, which may damage the top layer of the ONO film.

For example, hydrogen fluoride HF is used for etching sacrificial or residual oxides on the substrate. In representative processes, 500:1 diluted hydrogen fluoride DHF is applied having an etch rate for silicon dioxide of about five Angstroms per minute. Also, a cleaning solution known as SCI (NH₄OH:H₂O₂:H₂O in, for examples, a 1:1:5 mixture or a 1:1:40 mixture at a temperature of 45 to 70 degrees Celsius) is used for removing particles on the substrate, having etching rate for silicon dioxide of about 0.2 Angstroms per minute. Some processes also use a cleaning solution known as SC2 (HCl:H₂O₂:H₂O in, for examples, a 1:1:5 mixture or a 1:1:40 mixture at a temperature of 45 to 70 degrees Celsius) is used for removing metal ions or elements. The typical cleaning process will involve a sequence of cleaning steps including DHF, SC1 and SC2. The diluted hydrogen fluoride is used to remove a certain amount oxide. After oxide removal, SC1 is used to further clean the substrate and remove particles. If necessary, the SC2 solution is used to remove metal ions from the wafer surface.

On devices including an ONO film, cleaning processes may eliminate the hydrogen fluoride rinse in order to protect the top surface of the ONO film. However, the SC1 process still damages the top layer of the ONO film. Because the thicknesses of the layers of the ONO film are critical, such damage is not acceptable. Thus, extra process steps are required to protect the ONO film from damage during the cleaning steps. Alternately, cleaning solutions that do not damage oxide must be used. However, such cleaning solutions are inferior in many settings.

Accordingly, it is desirable to provide a process for forming an ONO film for use in integrated circuits that prevents damage during cleaning processes required after formation of the film. Furthermore, it is desirable that such process preserve the critical dimensions of the thicknesses of the layers of the ONO film. Finally, it is desirable that such process eliminate costly steps required in the prior art to protect the integrity of the ONO film during manufacture.

### SUMMARY OF THE INVENTION

The present invention provides a method for manufacturing an integrated circuit device that includes forming a multi-layer film, such as an ONO film, on a surface of the substrate, the multi-layer film including the first layer of silicon oxide, a middle layer of silicon nitride, and a top layer of silicon oxide. The top layer of silicon oxide has an exposed surface. Next, the process involves exposing the exposed surface of the top layer of the multi-layer film to a plasma containing nitrogen radicals, to form a nitrided layer of oxide on the exposed surface. Cleaning steps are then applied to the substrate, for example to prepare the substrate for formation of gate oxides in regions remote from the multi-layer film.

The nitrided layer of oxide on the top layer of silicon oxide in the multi-layer film has a thickness sufficient to protect the multi-layer film from damage during the cleaning steps. The nitrided layer comprises silicon oxynitride compounds (SiₓO_{y}N_{z}) having a thickness of for example, about 1 to 10 Angstroms.

Thus, a cleaning process can be utilized that may attacks silicon dioxide to a greater degree than the nitrided layer, without significant damage to the multi-layer film. This way, greater precision and uniformity in the manufacturing of ONO films is provided.

One process of exposing the top layer of the multi-layer film to a plasma containing nitrogen radicals is referred to as remote plasma nitridation RPN. (See, U.S. Pat. No. 6,261,973 B1, entitled REMOTE PLASMA NITRIDATION TO ALLOW SELECTIVELY ETCHING OXIDE) In preferred systems, the substrate is raised to temperature in a range of about 600 to 900 degrees Celsius for a time period of about 120 to 180 seconds, while a flow of plasma containing nitrogen radicals is applied to the exposed services.

After formation of the nitrided layer, the substrate is cleaned using a cleaning agent, such as HF, SC1, and SC2, in a process that exposes the nitrided layer to the cleaning agent. After cleaning, gate oxide is formed in regions of the device away from the ONO film. After formation of the gate oxide, a polysilicon or other conductive material is deposited over the gate oxide, and over the ONO film, for use as logic gates and/or control gates for memory devices.

The present invention is applied in the manufacturing of integrated circuit memory devices including floating gate memory devices in which ONO films are used for interpoly dielectrics. Also, the present invention can be applied in integrated circuit memory devices including SONOS cells.

Therefore, the present invention involves nitrifying the top oxide in an ONO film to form a nitrided oxide layer. Since the top oxide of the ONO film has a nitrided layer on it, loss of the top oxide in following cleaning steps is decreased or prevented. In this way, the total thickness of the ONO film does not change during the cleaning steps. Accordingly, greater control over the total thickness is of the ONO film is achieved allowing more uniform characteristics to be maintained in the device.

Other aspects and advantages of the present invention can be seen on review of the drawings, the detailed description and the claims, which follow.

### BRIEF DESCRIPTION OF THE DRAWINGS

FIG. 1 is a simplified diagram of an integrated circuit including an ONO film.

FIG. 2 illustrates remote plasma nitridation of an ONO film according to the present invention.

FIG. 3 is a flowchart of a process for remote plasma nitridation suitable for use with the present invention.

FIG. 4 illustrates a cleaning step after remote plasma nitridation of the ONO film on the integrated circuit of FIG. 1.

FIG. 5 illustrates the formation of gate oxides on the integrated circuit after the cleaning step of FIG. 4.

FIG. 6 illustrates formation of gate/control gate electrodes after formation of the gate oxides.

### DETAILED DESCRIPTION

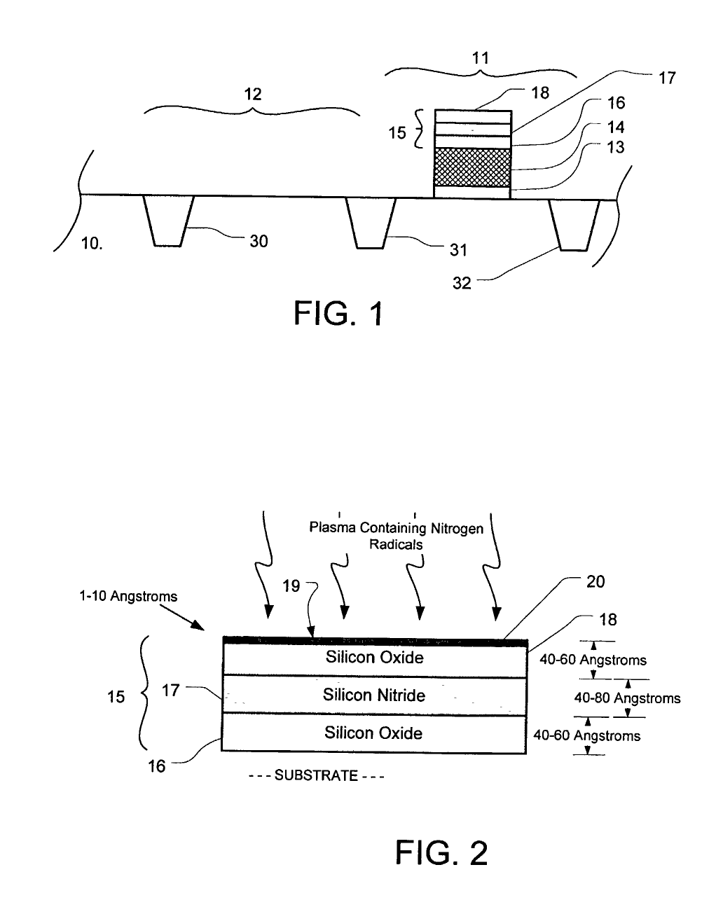

A detailed description of embodiments of the present invention is provided with reference to FIGS. 1 through 6. FIG. 1 provides a simplified diagram of an integrated circuit memory device including in ONO film in which the present invention is applied. The integrated circuit memory device includes a substrate 10, which includes a first region 11 and a second region 12. Memory cells are to be formed in the first region 11, and peripheral logic is to be formed in the second region 12. Isolation structures 30, 31 and 32 are shown in the substrate. In this example, a memory cell being manufactured is shown, including a tunnel oxide 13, a polysilicon floating gate 14, and a multi-layer film 15. In the multi-layer film includes a first layer 16 of silicon dioxide, a middle layer 17 of silicon nitride, and a top layer 18 of silicon dioxide. In this example, the multi-layer film will act as an interpoly dielectric in the floating gate memory cell being formed. The thicknesses of the layers within the multi-layer film have an impact on uniformity of performance of the memory cells in the array. Therefore, it is desirable to maintain such thicknesses as uniform as possible across the array.

The multi-layer film is formed using techniques known in the art in the region 11 of the device. The multi-layer film is not formed in the region 12, or in the alternative is removed from the region 12 during manufacturing steps.

According to the present invention, remote plasma nitridation is applied to the substrate shown in FIG. 1. FIG. 2 shows an enlarged view of the multi-layer film for one embodiment of the invention. The multi-layer film 15 as shown in FIG. 2 includes the first layer of silicon oxide 16, the middle layer of silicon nitride 17, and the top layer of silicon oxide 18. Other embodiments may include additional layers of material that contribute to the function of the interpoly dielectric, as suits the needs of the particular implementation. For example, an additional layer of silicon nitride, or silicon oxynitride compounds, may be formed beneath the first layer of silicon oxide. In another example, additional layers of silicon dioxide and silicon nitride may be included between the middle layer and the top layer to establish an ONONO multi-layer film.

In this example, the first layer of silicon oxide 16 has a thickness in the range of 40 to 60 Angstroms. In other examples, the first layer of silicon oxide has a thickness in a range of 80 to 150 Angstroms. The middle layer of silicon nitride has a thickness in the range of 40 to 80 Angstroms. The top layer of silicon oxide has a thickness in the range of 40 to 60 Angstroms. Of course, the thicknesses of the layers of the multi-layer film are adapted in various embodiments to suit the needs of particular uses of the film.

As illustrated in FIG. 2, the exposed surface 19 of the top silicon oxide layer 18 is exposed to a plasma containing nitrogen radicals to form a nitrided layer of silicon oxide 20. The nitrided layer of silicon oxide comprises silicon oxynitride compounds SiₓO_{y}N_{z}. In a preferred embodiment, the nitrided layer of silicon oxide has a thickness in the range of 1 to 10 Angstroms.

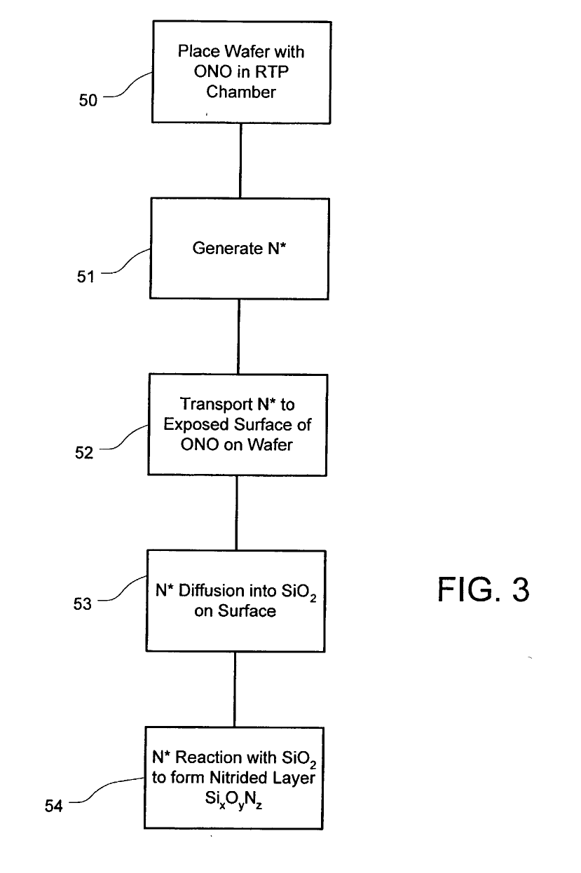

FIG. 3 shows a flowchart for a remote plasma nitridation according to the present invention. First, the wafer including the multi-layer film having an exposed surface is placed in a rapid thermal process RTP chamber (step 50). Nitrogen radicals are generated for delivery to the wafer (step 51). Nitrogen radicals are generated for example by exciting nitrogen gas with microwave energy in a site remote from the wafer. A portion of the nitrogen gas molecules breakdown and become nitrogen radicals. Next, the nitrogen radicals are transported to the exposed surface of the multi-layer film on the wafer in the RTP chamber (step 52). The transport occurs, for examples, by flowing the nitrogen gas having the nitrogen radicals into the chamber, or by flowing a mixture of the nitrogen gas with helium into the chamber. Next, nitrogen radicals diffuse into the exposed surface of the silicon dioxide (step 53). The nitrogen radicals which are diffused into the silicon dioxide react by breaking the silicon—oxide bonds and recombining to form silicon oxynitride compounds (step 54).

During the nitridation of the top oxide layer of the multi-layer film, the wafer is heated to temperature in the range of 600 to the 900 degrees Celsius. The gas containing nitrogen radicals is delivered to the substrate for time in the range of 120 to 180 seconds. The total flow rate of the carrier including nitrogen radicals ranges from 2 slm to 3 slm. The carrier gas comprises nitrogen or, for example, mixture of nitrogen with helium or other inert gases. The carrier comprises up to 50 percent helium, in some embodiments. These parameters are optimized according to a particular implementation to achieve sufficient nitridation of the top oxide layer to maintain the integrity of the layer during subsequent cleaning steps. For example, a nitrided layer is formed in preferred embodiments having a thickness of 1 to 10 Angstroms.

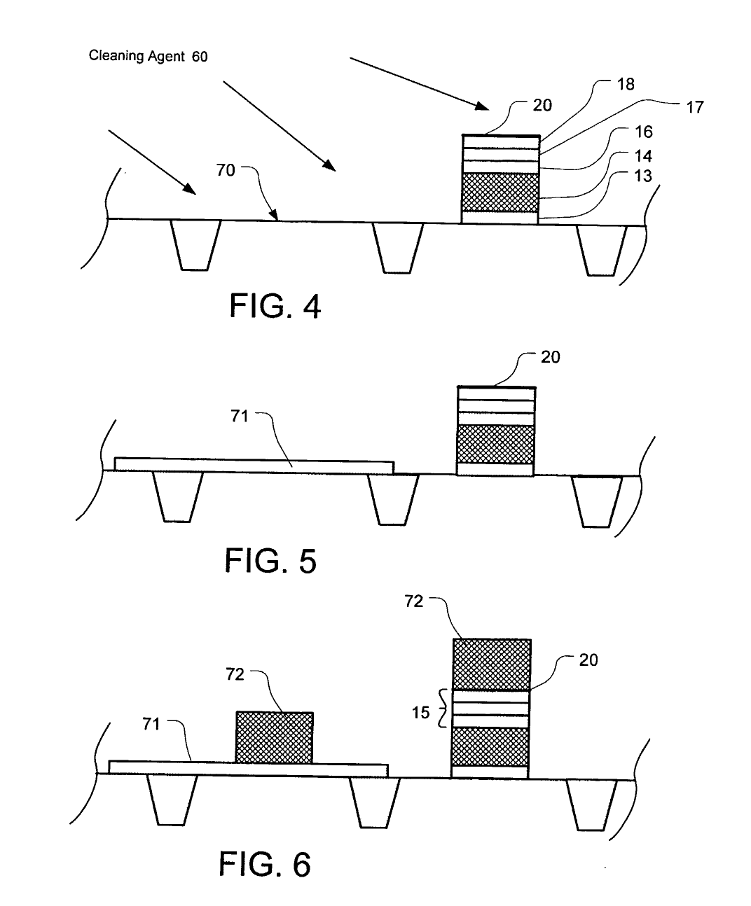

FIGS. 4-6 illustrate subsequent steps in the manufacturing an integrated circuit memory device according to the present invention. In FIG. 4, structure of FIG. 1 is illustrated, after remote plasma nitridation is used to form a nitrided layer 20 on the top oxide layer 18 of the multi-layer film. After the remote plasma nitridation, the cleaning process is used, which includes exposing the substrate to the cleaning agent 60, and to prepare the substrate in the region 70 for formation of a gate oxide layer to be used in formation of peripheral circuits. Cleaning agents including diluted hydrogen fluoride DHF, and SC1 are applied in various embodiments, with the nitrided layer 20 protecting the ONO film. In addition, the cleaning agent SC2 is used in some embodiments. In yet other embodiments, cleaning steps involving a sequence of multiple cleaning agents, including for example all three of DHF, SC1 and SC2 are utilized.

As shown in FIG. 5, after the cleaning process, gate oxide 71 is formed in regions used for peripheral circuitry. As shown in FIG. 6, a conductive material 72, such as polysilicon, is applied over the gate oxide 71, to form gate electrodes for the peripheral logic circuits. In some embodiments, the conductive material 72 is also applied over the multi-layer film 15 to act as control gate electrodes for floating gate devices which incorporate the multi-layer film.

The present invention has been described with reference to the manufacture of integrated circuit memory devices. However, it is applicable for any process where precise control of top oxide thickness in a multi-layer film is desirable, when such top oxide is exposed to wet cleaning processes which may etch or otherwise damage the oxide.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A method for manufacturing an integrated circuit device, comprising:
forming a multi-layer film on a surface of a substrate, the multi-layer film including a first layer of silicon oxide, a middle layer of silicon nitride, and a top layer of silicon oxide, the top layer having an exposed surface; and
exposing said exposed surface to a plasma containing nitrogen radicals, to form a nitrided layer of oxide on the exposed surface.

2. The method of claim 1, wherein the nitrided layer has a thickness about 1 to 10 Angstroms.

3. The method of claim 1, wherein said nitrided layer comprises SiₓO_{y}N_{z}.

4. The method of claim 1, wherein said exposing said exposed surface to a plasma containing nitrogen radicals is performed while said substrate has a temperature in a range of about 600 to 900 degrees Celsius.

5. The method of claim 1, wherein said exposing said exposed surface to a plasma containing nitrogen radicals is performed while said substrate has a temperature in a range of about 600 to 900 degrees Celsius for a time period of about 120 to 180 seconds.

6. The method of claim 1, including after said exposing said exposed surface to a plasma containing nitrogen radicals, cleaning the substrate using a cleaning agent comprising SC1 in a process exposing the nitrided layer to said cleaning agent.

7. The method of claim 1, including after said exposing said exposed surface to a plasma containing nitrogen radicals, cleaning the substrate using a cleaning agent comprising HF in a process exposing the nitrided layer to said cleaning agent.

8. The method of claim 1, including after said exposing said exposed surface to a plasma containing nitrogen radicals, cleaning the substrate using a cleaning agent that damages silicon dioxide in a process exposing the nitrided layer to said cleaning agent.

9. The method of claim 1, including after said exposing said exposed surface to a plasma containing nitrogen radicals,
cleaning the substrate using a cleaning agent that damages silicon dioxide in a process exposing the nitrided layer to said cleaning agent; and
forming a gate oxide in regions on the substrate after said cleaning.

10. The method of claim 1, including after said exposing said exposed surface to a plasma containing nitrogen radicals,
cleaning the substrate using a cleaning agent that damages silicon dioxide in a process exposing the nitrided layer to said cleaning agent; and
forming a conductive layer on said substrate after said cleaning, the conductive layer contacting the nitrided layer.

11. A method for manufacturing an integrated circuit device, comprising:
forming a film on a surface of a substrate, the film having a top layer of silicon oxide, the top layer having an exposed surface;
exposing said exposed surface to a plasma containing nitrogen radicals, whereby a nitrided layer of oxide is formed on the exposed surface;
cleaning the substrate using a cleaning agent in a process exposing the nitrided layer to said cleaning agent; and
forming a gate oxide in regions on the substrate after said cleaning.

12. The method of claim 11, wherein the nitrided layer has a thickness about 1 to 10 Angstroms.

13. The method of claim 11, wherein said nitrided layer comprises SiₓO_{y}N_{z}.

14. The method of claim 11, wherein said exposing said exposed surface to a plasma containing nitrogen radicals is performed while said substrate has a temperature in a range of about 600 to 900 degrees Celsius.

15. The method of claim 11, wherein said exposing said exposed surface to a plasma containing nitrogen radicals is performed while said substrate has a temperature in a range of about 600 to 900 degrees Celsius for a time period of about 120 to 180 seconds.

16. The method of claim 11, wherein said cleaning the substrate includes using a cleaning agent comprising SC1.

17. The method of claim 11, wherein said cleaning the substrate includes using a cleaning agent comprising HF.

18. The method of claim 11, including after said cleaning
forming a conductive layer on said substrate after said cleaning, the conductive layer contacting the nitrided layer.

19. The method of claim 11, wherein the nitrided layer has a thickness sufficient to protect the top layer from said cleaning agent.

20. A method for manufacturing an integrated circuit memory device, comprising:
forming a multi-layer film on a surface of a substrate in a memory array region, the multi-layer film including a first layer of silicon oxide, a middle layer of silicon nitride, and a top layer of silicon oxide, the top layer having an exposed surface;
exposing said exposed surface to a plasma containing nitrogen radicals, whereby a nitrided layer of oxide is formed on the exposed surface, the nitrided layer having a thickness in a range of about 1 to 10 Angstroms;
cleaning the substrate using a cleaning agent in a process exposing the nitrided layer to said cleaning agent;
forming a gate oxide in regions on the substrate outside said memory array region after said cleaning;
forming a conductive layer on said substrate after said cleaning, the conductive layer contacting the nitrided layer and said gate oxide; and
patterning said conductive layer.

21. The method of claim 20, wherein said nitrided layer comprises SiₓO_{y}N_{z}.

22. The method of claim 20, wherein said exposing said exposed surface to a plasma containing nitrogen radicals is performed while said substrate has a temperature in a range of about 600 to 900 degrees Celsius.

23. The method of claim 20, wherein said exposing said exposed surface to a plasma containing nitrogen radicals is performed while said substrate has a temperature in a range of about 600 to 900 degrees Celsius for a time period of about 120 to 180 seconds.

24. The method of claim 20, wherein said cleaning the substrate includes using a cleaning agent comprising SC1.

25. The method of claim 20, wherein said cleaning the substrate includes using a cleaning agent comprising HF.
